(19) United States
(12) Patent Application Publication
(10) Pub. No.: US 2026/0040917 A1
(43) Pub. Date: Feb. 5, 2026

(54) THERMAL STRUCTURES FOR HYBRID BONDING

(71) Applicant: Micron Technology, Inc., Boise, ID (US)

(72) Inventors: Bharat Bhushan, Boise, ID (US); Amy Rae Griffin, Boise, ID (US); Jonathan Thomas Doebler, Boise, ID (US); Angela Tigue, Boise, ID (US); Akshay N. Singh, Boise, ID (US)

(21) Appl. No.: 19/275,754

(22) Filed: Jul. 21, 2025

Related U.S. Application Data
(60) Provisional application No. 63/677,834, filed on Jul. 31, 2024.

(51) Int. Cl. H01L 23/48; H01L 21/768; H01L 23/00; H01L 23/367; H01L 23/528; H01L 25/18; H10B 80/00; H10D 80/30

(52) U.S. Cl. CPC H01L 23/481; H01L 21/76877; H01L 23/528; H01L 24/08; H01L 24/80; H01L 23/3677; H01L 25/18; H01L 2224/08145; H01L 2224/80895; H01L 2224/80896; H01L 2225/06589; H01L 2924/1431; H01L 2924/14361; H10B 80/00; H10D 80/30

(57) ABSTRACT

Methods, systems, and devices for thermal structures for hybrid bonding are described. Thermal structures may be formed within stacked memory devices, such as memory dies, to increase heat dissipation and thermal conductivity in a system. For example, a device may include one or more active contacts coupled with through-silicon vias (TSVs) extending through a silicon substrate, which may transport signaling or power. The device may also include one or more inactive contacts that may not be directly coupled with one or more TSVs. To increase heat dissipation, one or more vias may be formed between non-active contacts and a metal layer. In some examples, vias may be formed for conductors that are at least partially above a respective metal layer conductor. In some cases, a system may include stacks of bonded pairs of devices, or stacks of bonded trios of devices.

### CROSS REFERENCE

The present Application for Patent claims priority to U.S. Patent Application No. 63/677,834 by Bhushan et al., entitled “THERMAL STRUCTURES FOR HYBRID BONDING,” filed Jul. 31, 2024, which is assigned to the assignee hereof, and which is expressly incorporated by reference in its entirety herein.

### TECHNICAL FIELD

The following relates to one or more semiconductor systems, including thermal structures for hybrid bonding.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells. Memory devices may be stacked and hybrid bonded (e.g., conductive and insulative materials fused). Thermal resistance within a memory device or between bonded memory devices in a stack may in some cases limit performance of a memory system.

### BRIEF DESCRIPTION OF THE DRAWINGS

FIG. 1 shows an example of a system that supports thermal structures for hybrid bonding in accordance with examples as disclosed herein.

FIG. 2 shows an example of a system that supports thermal structures for hybrid bonding in accordance with examples as disclosed herein.

FIGS. 3A and 3B show examples of systems that support thermal structures for hybrid bonding in accordance with examples as disclosed herein.

FIGS. 4A, 4B, 4C, and 4D show an example of a system that supports thermal structures for hybrid bonding in accordance with examples as disclosed herein.

FIG. 5 shows an example of a system that supports thermal structures for hybrid bonding in accordance with examples as disclosed herein.

FIG. 6 shows an example of a system that supports thermal structures for hybrid bonding in accordance with examples as disclosed herein.

FIGS. 7 and 8 show flowcharts illustrating a method or methods that support thermal structures for hybrid bonding in accordance with examples as disclosed herein.

### DETAILED DESCRIPTION

Some semiconductor systems (e.g., memory systems, processor systems) may include one or more stacks of semiconductor memory components (e.g., semiconductor memory dies) that are stacked with one or more logic dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

A height of stacks of memory dies in HBM or 3D stacked memory systems may in some cases be limited based on a thermal load or ability of a memory system to expel or dissipate heat within each stack. For example, as memory die stacks increase in height, thermal resistance within and between stacked dies may increase, reducing an ability of a system to disperse heat within devices and across a stack, as well as to expel heat from the system. Some devices may include a quantity of contacts hybrid bonded with other dies, including contacts for electrical coupling for power coupling or signaling. Devices may also include one or more contacts that may be electrically isolated (e.g., floating), or that may not be directly coupled with one or more active lines. For example, certain layers such as metal layers may have fill portions that are inserted for density matching, but are not electrically connected.

Thermal structures may be formed within stacked memory dies to further distribute heat. For example, a device (e.g., a semiconductor die) may include one or more through-silicon vias (TSVs), or vias extending through a silicon substrate, which may be coupled with a metal layer, where portions of the metal layer coupled with the TSVs may couple with active contacts to enable communication between stacked devices (e.g., power rails, signal rails, where a rail may be a conductive path for delivery of power or signals, and may extend through one or more dies). The device may also include one or more inactive contacts that may not be directly coupled with one or more TSVs. To improve thermal conductivity, additional vias may be placed between non-active contacts and the metal layer to improve heat dissipation provided by both active contacts and inactive contacts. In some examples, vias may be formed for conductors that are at least partially above respective metal layer conductors (e.g., landing pad). In some examples, a system may include stacks of bonded pairs of devices in such a configuration. By adding additional vias to inactive, or active, contacts, a thermal conductivity of a system may increase, enabling higher die stacks and reducing a thermal load to improve performance. Reducing a thermal load may also increase a power capability for a memory system. Further, some systems may include stacks of more than two hybrid bonded devices, further increasing a device density and challenges in thermal conductivity of the system.

In addition to applicability in memory systems as described herein, techniques for forming thermal structures for hybrid bonding may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing a thermal load on a system, allowing faster clock speeds and higher power draw. Increasing thermal conductivity may also enable higher stacks of devices for greater performance and scaling.

In addition to applicability in memory systems as described herein, techniques for forming thermal structures for hybrid bonding may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving thermal performance, leading to longer lifetime and thus reducing an amount of material in manufacturing new devices, among other benefits.

Features of the disclosure are illustrated and described in the context of systems and architectures. Features of the disclosure are further illustrated and described in the context of systems and flowcharts.

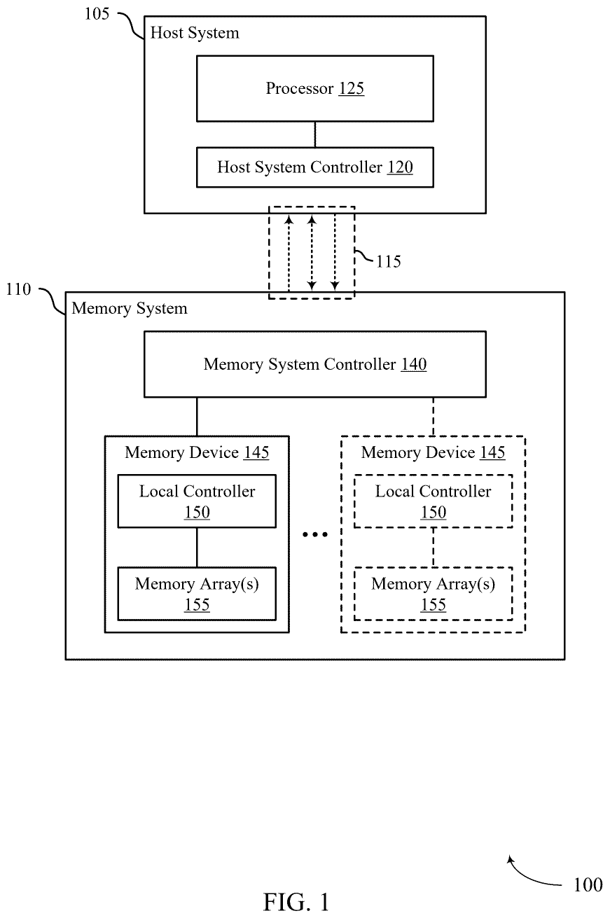

FIG. 1 shows an example of a system 100 that supports thermal structures for hybrid bonding in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a stacked semiconductor system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

In some examples of a system 100, one or more conductive thermal structures may be placed within stacked dies to further distribute heat. For example, the memory system 110 may include a stack of dies associated with the memory system 110 (e.g., associated with memory array(s) 155, associated with memory device(s) 145), where a die of the stack may include a quantity of active contacts and a quantity of inactive contacts (e.g., electrically isolated, not directly coupled with active lines) hybrid bonded with a second die. The die may also include one or more TSVs coupled with a metal layer. In some cases, portions of the metal layer coupled with the TSVs may also couple with active contacts to enable communication between dies and die stacks (e.g., power rails, signal rails for communicating data between memory devices 145 and the memory system controller 140 or controllers or processors of the host system 105), where the die may include contacts hybrid bonded with contacts of another die. To improve thermal conductivity, additional vias may be placed between non-active contacts and the metal layer. In some cases, the system 100 may include stacks of bonded pairs of memory dies, or may include stacks of bonded trios of dies to further increase die density and thermal conductivity. In some examples, a stack of dies may include a total quantity of dies, including, for example, at least 4, 8, 12, 16, 20, or 24 dies (e.g., bonded in pairs of 2 or trios of 3 dies).

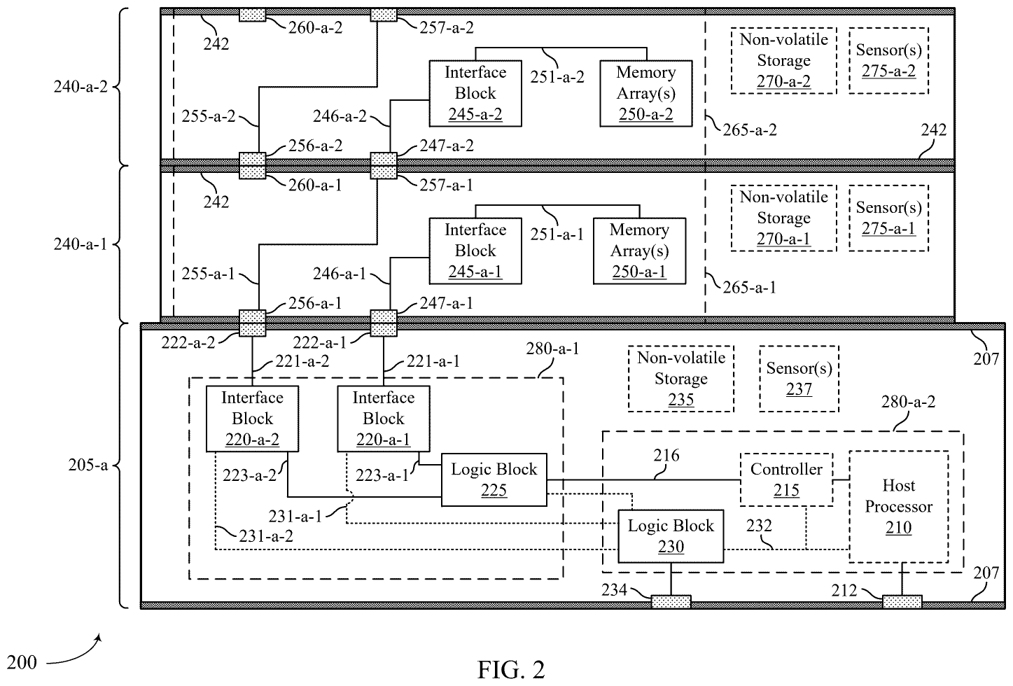

FIG. 2 shows an example of a system 200 (e.g., a semiconductor system, a system of coupled semiconductor dies, an HBM system, a 3D stacked memory system) that supports thermal structures for hybrid bonding in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations, a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 die and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with another contact 256 that is not coupled with other components, or with the contact 256-a-2 (e.g., where the bus 255-a-2 may be electrically isolated from one or more components), neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220). Further, in some examples, one or more conductive components, such as contacts 256 and 260 as described herein, may be added to the dies 240 for density matching (e.g., electrically isolated metal components). In some examples, the presence of the contacts may increase thermal conductivity between the dies 240. However, the contacts 256 or 260 of one die 240 may not be thermally connected via low thermal resistance paths within the die 240.

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245).

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof. In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

In some examples, although FIG. 2 may be described with reference to a 2:1 memory system configuration where two memory dies are coupled with one logic die, the techniques described herein may be implemented in other memory system configurations, such as a 4:1 configuration, a 4:2 configuration, a 2:2 configuration, a 8:1 configuration, a 12:1 configuration, a 16:1 configuration and so on, where an n:N configuration refers to a configuration with n memory dies and N logic dies. In some examples (e.g., in coupled DRAM systems, in 3D stacked memory systems), there may be multiple (e.g., 4, 6, 8) n:N configuration stacks (e.g., 8:1 configuration, 12:1 configuration, 16:1 configuration) on a processor (e.g., a CPU, a GPU).

In some examples of a system 200, one or more thermal structures may be placed within dies 240 to further distribute heat. For example, a die 240 may include a quantity of active contacts (e.g., contacts 257, 247, 256) and a quantity of inactive contacts (e.g., contacts 260, 256). The die 240 may also include one or more TSVs coupled with a metal layer, such as an RDL (e.g., a portion of a bus 246, or a bus 255). In some cases, portions of the metal layer coupled with the TSVs may also couple with active contacts to enable communication between dies 240 (e.g., power rails, signal rails), where the die may include contacts hybrid bonded with contacts of another die 240. To improve thermal conductivity, additional vias may be placed between non-active contacts and the metal layer. Further, the system 200 may include stacks of bonded pairs of dies 240, or may include stacks of bonded trios of dies 240. For example, a pair or trio of dies 240 may be hybrid bonded, where each pair or trio may be coupled with another pair or trio in a stacked configuration.

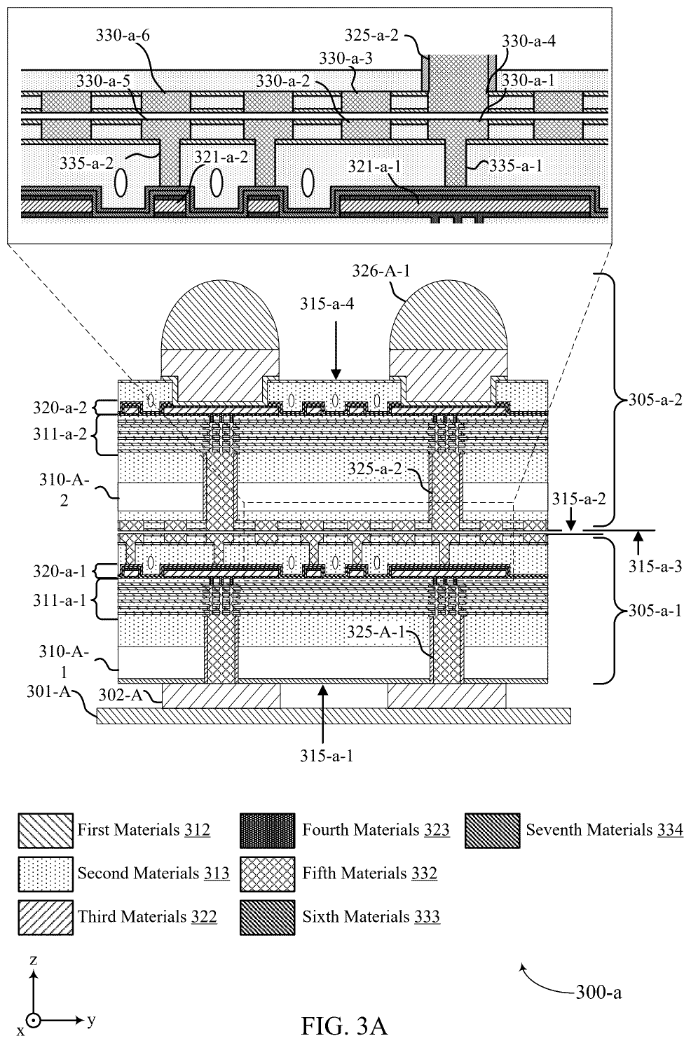

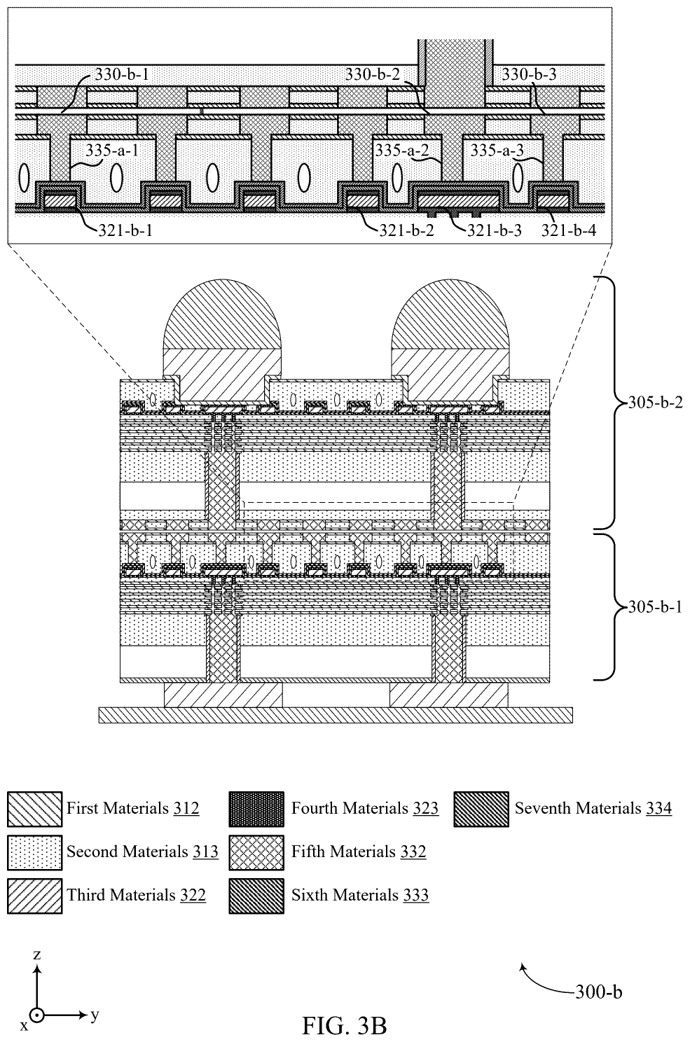

FIGS. 3A and 3B show examples of a system 300-a and a system 300-b (e.g., a semiconductor system, a system of semiconductor dies) that support thermal structures for hybrid bonding in accordance with examples as disclosed herein. In some cases, FIGS. 3A and 3B may illustrate a cross-section of the systems 300-a and 300-b. Aspects of the systems 300-a and 300-b may further be described with reference to an x-direction, a y-direction, and a z-direction of the illustrated coordinate system, where the z-direction may be illustrative of a direction (e.g., a vertical direction, a thickness direction, a stack direction) that is orthogonal to or otherwise relative to a surface in an xy-plane (e.g., a substrate plane, a coupling plane) of the systems 300-a and 300-b. Although FIGS. 3A and 3B illustrate examples of relative dimensions and quantities of various features, aspects of the systems 300-a and 300-b may be implemented with other relative dimensions or quantities of such features in accordance with examples as disclosed herein. In some examples, FIGS. 3A and 3B may illustrate addition of one or more thermal components to devices 305 to increase thermal conductivity as described herein.

In the example of FIG. 3A, the system 300-a may include a device 305-a-1 (e.g., a first semiconductor device, a semiconductor die 240) and a device 305-a-2 that may be bonded (e.g., hybrid bonded) in a stack of one or more stacked devices 305, where the device 305-a-1 may be bonded or coupled with a material 301-a (e.g., a silicon wafer, a frame wafer, a dicing tape) using one or more conductive pads 302 (e.g., including a conductive pad 302-a). In some cases, the devices 305-a-1 and 305-a-2 may represent a bonded pair, or group of devices, that may be stacked with one or more other bonded pairs.

In some examples, the device 305-a-1 may include a substrate 310-a-1 between a surface 315-a-1 (e.g., a first surface) and a surface 315-a-2 (e.g., a second surface of the device 305-a-1), and in some cases a material stack 311-a-1 of alternating first materials 312 (e.g., a silicon carbon nitride) and second materials 313 (e.g., an insulative material, a silicon oxide). Additionally, or alternatively, the material stack 311-a-1 may include alternating insulating and conductive materials. In some examples, the device 305-a-1 may include a conductive layer 320-a-1 that may include a set of conductors 321 formed of third materials 322 (e.g., conductive materials, aluminum). The conductive layer 320-a-1 and the set of conductors 321 may be between the substrate 210-a-1 and the surface 215-a-2, and the material stack 211-a-1 may be between the substrate 210-a-1 and the conductive layer 320-a-1. Similarly, the device 305-a-2 may also include a substrate 310-a-2 (e.g., a second substrate) between a surface 315-a-3 and a surface 315-a-4 of the device 305-a-2 (e.g., a first and second surface, respectively). The device 305-a-2 may also include a conductive layer 320-a-2 of a set of conductors 321.

In some examples, a first subset of conductors 321 of the set of conductors 321 may be directly coupled with a set of respective vias 325 (e.g., first vias, TSVs) extending through the substrate 310-a-1. For example, a conductor 321-a-1 may be directly coupled with a via 325-a-1. In some cases, direct coupling may involve one component or material coupling with another component or material through one or more conductive elements without intervening semiconductor devices, channels, or switches, among other means. For example, the conductor 321-a-1 may directly couple with the via 325-a-1 using portions of a fourth material 323 (e.g., conductive material, titanium nitride TiN). Additionally, or alternatively, a second subset of conductors 321 of the set of conductors 321 may not be directly coupled with the set of respective vias 325. For example, the conductor 321-a-2 may involve one component or material coupling with another component or material through one or more intervening semiconductor devices, channels, or switches, among other means. For example, the conductor 321-a-2 may extend in the x direction and may couple at any point with one or more components (e.g., memory cells, transistors) to couple with the conductor 321-a-1 and the via 325-a-1. Additionally, or alternatively, the conductor 321-a-2 may be electrically isolated from one or more components.

The system 300-a may in some cases include one or more contacts 330 (e.g., contacts 257, 247, 256, 260). For example, the device 305-a-1 may include contacts 330-a-1 and 330-a-2, among other contacts 330, at the surface 315-a-2, while the device 305-a-2 may include one or more contacts 330 at the surface 315-a-3. In some cases, the contacts 330 may be formed using one or more fifth materials 332 (e.g., conductive materials, copper). The contacts 330 may in some cases be formed within one or more materials, such as within one or more second materials 313 (e.g., insulative materials). In some cases, contacts 330 of the device 305-a-1 may be hybrid bonded with one or more contacts 330 of the device 305-a-2. For example, the contacts 330-a-1 and 330-a-2 may be hybrid bonded with contacts 330-a-3 and 330-a-4 at a surface 315-a-3 of the device 305-a-2.

In some cases, the contacts 330-a-1 and 330-a-4 may couple directly with respective vias 325-a-1 and via 325-a-2, respectively (e.g., using one or more conductors or vias). In some examples, the contacts 330-a-2 and 330-a-3 may be electrically isolated from the vias 325-a-1 and 325-a-2 (e.g., due to an insulative material, such as a second material 313). For example, the contacts 330-a-2 and 330-a-3 may be used to improve a uniformity in a chemical mechanical polishing (CMP) operation or may be included to increase uniformity of hybrid bonding. In some cases, the via 325-a-2 may couple with a conductive pad 326-a-2 (e.g., solder ball), where the conductive pad 326-a-2 may be operable to couple the devices 305 with other devices 305 (e.g., to couple with other pairs of bonded devices). In some examples, additional sixth materials 333 and seventh materials 334 may be included. For example, one or more sixth materials 333 on the conductor 321-a-1 may represent an insulative material (e.g., a silicon oxide) while the seventh materials 334 may be a different material (e.g., a silicon nitride). In some examples, hybrid bonding the devices 305-a-1 and 305-a-1 may represent a wafer face to back hybrid bond. For example, the bonding in FIG. 3A may illustrate a bonding of a face, or front end of line (FEOL), of the device 305-a-1 with a back, or back end of line (BEOL), of the device 305-a-2. Additionally, or alternatively, other configurations may be supported (e.g., back to back, face to face, including supporting circuitry and TSVs to support bonding).

In some cases, the system 300-a may include a set of contacts that are electrically isolated from the conductive layer 320, such as the contact 330-a-2. Electrical insulation of the one or more contacts 330 may result in higher thermal resistance, which may limit a functionality or height of a stack including the devices 305 (e.g., HBM stacks).

Additional formation of thermal structures (e.g., thermally conductive materials or structures to dissipate heat) may improve a thermal distribution and reduce thermal resistance in one or more device 305. For example, FIG. 3A may illustrate a first example, where the device 305-a-1 may include a via 335-a-2 directly coupling a contact 330-a-5 with a conductor 321, such as the conductor 321-a-2. The device 305-a-1 may also include additional vias 335. In some cases, adding the vias 335 may increase a density of vias and other conductors within the device 305-a-1, and thus may increase thermal conductivity, as well as increase a uniformity across a die or between devices, improving efficiency in heat dissipation. For example, added thermal structures may result in a closer density between material layers of a device 305, as well as uniform density across layers.

Other vias 335 included for active connections may further contribute to heat dissipation. For example, the contact 330-a-1 may directly couple with the via 325-a-1 based on being coupled with a via 335-a-1. In some cases, the contact 330-a-5 may not directly couple with the set of respective first vias based on being coupled with the via 335-a-2 via and the conductor 321-a-2 (as the conductor 321-a-2 may not be directly coupled with active circuitry). In some cases, there may remain one or more contacts 330 in the device 305-a-1 without respective vias 335 (e.g., the contact 330-a-2).

In some examples, one or more contacts 330 may be electrically coupled with one or more signals based on being coupled with one or more respective conductors 321 (e.g., one or more conductors 321 may be “live” rails for live hybrid bond structure). Additionally, or alternatively, one or more contacts 330 and one or more respective conductors 321 may be electrically isolated from one or more signals (e.g., one or more conductors 321 may be floating). In some examples, one or more conductive lines may be widened to couple with more contacts 330. For example, an electrically isolated conductor 321 or a conductor 321 that is not directly coupled with a via 325 may be widened to couple with multiple contacts 330. Further, an active conductor 321, such as the conductor 321-a-1, may be widened and/or coupled with multiple contacts 330 (as such contacts may be floating and thus may not short a signal or current/voltage from the via 325-a-1). In some cases, conductors 321 may be referred to as landing pads for respective contacts 330 or vias 335.

In some examples, contacts 330 and vias 335 described herein may illustrate examples of different hybrid bond structures. For example, the contact 330-a-5 and the via 335-a-2 may represent a thermal hybrid bonding structure that may be electrically isolated, but may dissipate heat through the coupling. The contact 330-a-1 and the via 335-a-1 may represent a live hybrid bond structure involving a live connection, or TSV, such as the via 325-a-1, while the contact 330-a-2 may represent a CMP fills hybrid bond structure (e.g., a structure used to control a CMB operation).

Hybrid bonding of conductors 330 across both devices may also contribute to increased thermal conductivity. For example, the contact 330-a-5 may be hybrid bonded with a contact 330-a-6 of the device 305-a-2, where the via 335-a-2 may couple the contact 330-a-5, the contact 330-a-6, and the conductor 321-a-2 together across both devices 305, improving thermal conductivity between devices.

In some examples, any quantity of contacts 330 may be equipped with vias 335. For example, FIG. 3B may illustrate an example of a system 300-b that may include a via 335 for a relatively large quantity of contacts 330 (e.g., for a majority of contacts 330, for each contact 330). For example, the system 300-b may include devices 305-b-1 and 305-b-2 and contacts 330-b with various first materials 312, second materials 313, third materials 322, fourth materials 323, fifth materials 332, sixth materials 333, and seventh materials 334 similar to the system 300-a in FIG. 3A. In some cases, the device 305-b-1 may include a via 335 for each of contacts 330-b-1 through 330-b-3, including contacts coupled with a TSV, such as a contact 330-b-2. For example, the device 305-b-1 may include vias 335-a-1 through 335-a-2 and 335-a-3. In some examples, each contact 330 of the device 305-b-1 may be coupled with a respective via 335 based on the contact 330 extending at least partially over a respective conductor 321. For example, the contact 330-b-1 may extend at least partially over a conductor 321-b-1. In some cases, the system 300-b may have a greater density of conductors 321 (e.g., landing pads), vias 335, or both, compared to the system 300-a. For example, in place of the conductor 321-a-1, there may be three conductors 321-a-2, 321-a-3, and 321-a-4 in the system 300-b, where each conductor 321 may be coupled with a respective via 335. In some cases, a greater density of conductors 321 or vias 335 may result in a higher thermal conductivity (e.g., lower thermal resistance) in the system 300-b.

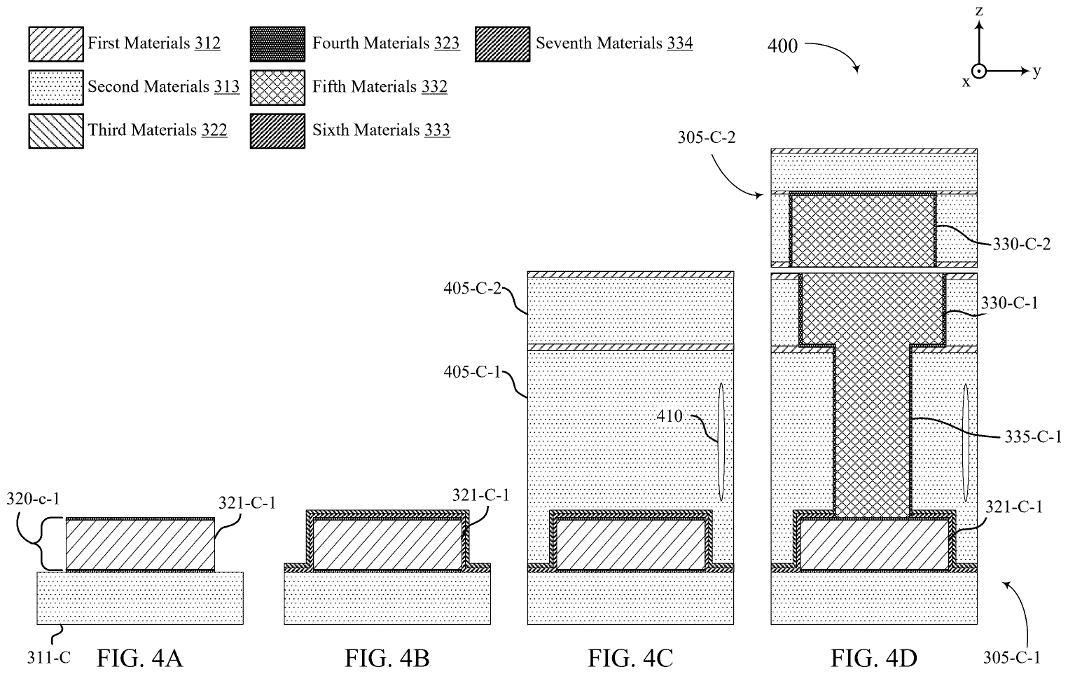

FIGS. 4A, 4B, 4C, and 4D show an example of a method of manufacturing a system 400 that supports thermal structures for hybrid bonding in accordance with examples as disclosed herein. For example, FIGS. 4A-4D may illustrate multiple fabrication operations for forming a first device 305 (e.g., the device 305-a-1, the device 305-b-1) and a second device 305 (e.g., the device 305-a-2, the device 305-b-2), and bonding the two devices 305 together. Aspects of the system 400 may further be described with reference to an x-direction, a y-direction, and a z-direction of the illustrated coordinate system, where the z-direction may be illustrative of a direction (e.g., a vertical direction, a thickness direction, a stack direction) that is orthogonal to or otherwise relative to a surface in an xy-plane (e.g., a substrate plane, a coupling plane) of the system 400. Although FIGS. 4A-4D illustrate examples of relative dimensions and quantities of various features, aspects of the system 400 may be implemented with other relative dimensions or quantities of such features in accordance with examples as disclosed herein. In some examples, FIGS. 4A and 4B may illustrate device formation processes as described herein.

In the example of FIG. 4A, a first set of one or more fabrication operations may include forming a conductive layer 320-c-1 including a set of conductors 321 (e.g., aluminum), such as a conductor 321-c-1, on a surface of a material stack 311-c (e.g., a material stack 311 formed on a substrate 310). The first set of one or more fabrication operations may also include depositing a fourth material 323 (e.g., titanium nitride). Similarly, in the example of FIG. 4B, a second set of one or more fabrication operations may include depositing sixth materials 333 (e.g., a silicon oxide) and seventh materials 334 (e.g., a silicon nitride) over the fourth material 323.

In the example of FIG. 4C, a third set of one or more fabrication operations may include depositing one or more insulating materials over a surface of the conductive layer 320. For example, the third set may include depositing a second material 313 (e.g., a silicon oxide). In some cases, the second material 313 may include multiple portions, including a portion 405-c-1 and a portion 405-c-2. In some cases, a second thin layer of a first material 312 may be deposited over each of the portions 405-c-1 and 405-c-2, which may separate the portions. In some examples, the formation process may fill one or more cavities. Additionally, or alternatively, the formation process may leave one or more air gaps 410.

In the example of FIG. 4D, a fourth set of one or more fabrication operations may include forming a set of vias 335, extending through the portion 405-c-1 of the second material 313 (e.g., insulating material). For example, a via 335-c-1 may be formed. The fourth set of one or more fabrication operations may also include forming one or more contacts 330, including a contact 330-c-1. To form the vias 335 (and contacts 330), the formation process may include etching the portions 405-c-1 and 405-c-2 of the second material 313 (and etching the first materials 312, sixth materials 333, and seventh materials 334) to form a set of multiple cavities, and depositing one or more conductive materials within the cavities.

In some cases, the set of vias 335 may include a first subset of vias 335 coupled with a first subset of conductors 321 (e.g., coupled with one or more TSVs) and a second subset of vias 335 coupled with a second subset of conductors 321 (e.g., not directly coupled with TSVs). Further, the one or more contacts may include a first set of contacts 330 (e.g., directly coupled with TSVs) and a second set of contacts 330 (e.g., coupled with conductors 321 not directly coupled with TSVs) formed at a surface of the second material 313 and extending through the portion 405-c-2 of the second material 313. In some examples, conductors 321 (e.g., the conductor 321-c-1) and respective vias 335 (e.g., the via 335-c-1) may form ohmic contacts based on a fourth material 323 between a fifth material 332 of the vias 335 and a third material 322 of the conductors 321, where an ohmic contact may represent a direct coupling of the materials involved.

In some examples, the formation operations described herein may form one or more devices 305. For example, a device 305-c-1 (e.g., the device 305-a-1, the device 305-b-1) may be formed including the materials described. Further, a device 305-c-2 (e.g., the device 305-a-2, the device 305-b-2) may be formed using one or more additional operations including one or more of the same processes as described herein. In some cases, the device 305-c-2 may include one or more contacts 330, including a contact 330-c-2, and one or more first materials 312 and 313, among other materials. In some cases, the fourth set of one or more fabrication operations may include bonding the contacts 330 of the device 305-c-1 with the contacts 330 of the device 305-c-2. For example, the contact 330-c-1 may be hybrid bonded with the contact 330-c-2. The hybrid bonding may further involve bonding a surface of one or more first materials 312 or 313 of each device 305 together.

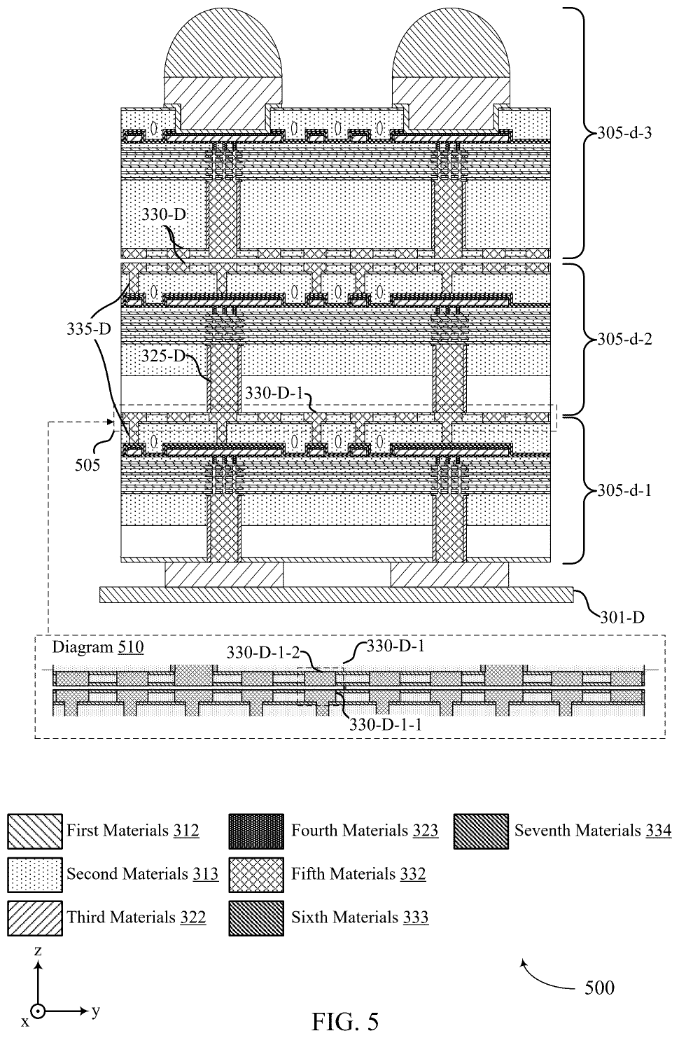

FIG. 5 shows an example of a system 500 that supports thermal structures for hybrid bonding in accordance with examples as disclosed herein. Aspects of the 500 may further be described with reference to an x-direction, a y-direction, and a z-direction of the illustrated coordinate system, where the z-direction may be illustrative of a direction (e.g., a vertical direction, a thickness direction, a stack direction) that is orthogonal to or otherwise relative to a surface in an xy-plane (e.g., a substrate plane, a coupling plane) of the system 500. Although FIG. 5 illustrate examples of relative dimensions and quantities of various features, aspects of the system 500 may be implemented with other relative dimensions or quantities of such features in accordance with examples as disclosed herein. In some examples, the system 500 may illustrate a system involving three bonded devices 305 of a stack of multiple bonded trios of devices.

For example, the system 500 may include a material 301-d on which devices 305-d-1, 305-d-2, and 305-d-3 may be stacked (e.g., during manufacture). In some cases, devices 305-d-1 and 305-d-2 may be examples of the devices 305-a-1, 305-b-1, or 305-c-1 while the device 305-d-3 may be an example of the devices 305-a-2, 305-b-2, or 305-c-2 including first materials 312, second materials 313, third materials 322, fourth materials 323, fifth materials 332, sixth materials 333, and seventh materials 334. Each of the devices 305-d-1 may be hybrid bonded via respective sets of contacts 330-d, and may include one or more vias 325-d and 335-d coupling the devices together. In some cases, the devices 305-d-1 and 305-d-2 may be illustrated to resemble a single device, but may represent two distinct devices (e.g., two dies) that may be hybrid bonded via respective contacts 330, and may each include a similar or different configuration as the other. For example, the elements at 505 may be represented by a diagram 510, and may include one or more contacts 330-d, including a contact 330-d-1. The contact 330-d-1 may represent 2 contacts, including a contact 330-d-1-1 of the device 305-d-1 and a contact 330-d-1-2 of the device 305-d-2 which may be hybrid bonded together, There may also be a layer of first materials 312 in between portions of the second materials 313 in the z direction, and in between portions of the fifth materials 332 of one or more contacts 330-d between the components 305-d-1 and 305-d-2 as illustrated in the diagram 510. In some cases, bonding three devices 305 together may further increase thermal conductivity, as a thermal conductivity between hybrid bonded devices may be greater than a thermal conductivity between two groups, or two trios, of bonded devices (e.g., coupled via conductive pads 326). Further, although pairs and trios of bonded devices 305 may be illustrated herein with respect to FIGS. 3A-5, any quantity of devices 305 may be bonded and stacked with other devices 305. In some cases, pairing two or three devices 305 and adding one or more thermal components (e.g., vias 335-d) may mitigate challenges in heat dissipation with higher and higher stacks 605 to expel heat (e.g., via a heat sink coupled with the stacks 605 or the device 615, or to dissipate heat vertically through a stack, enabling higher stacking of devices 305 as well as improving performance.

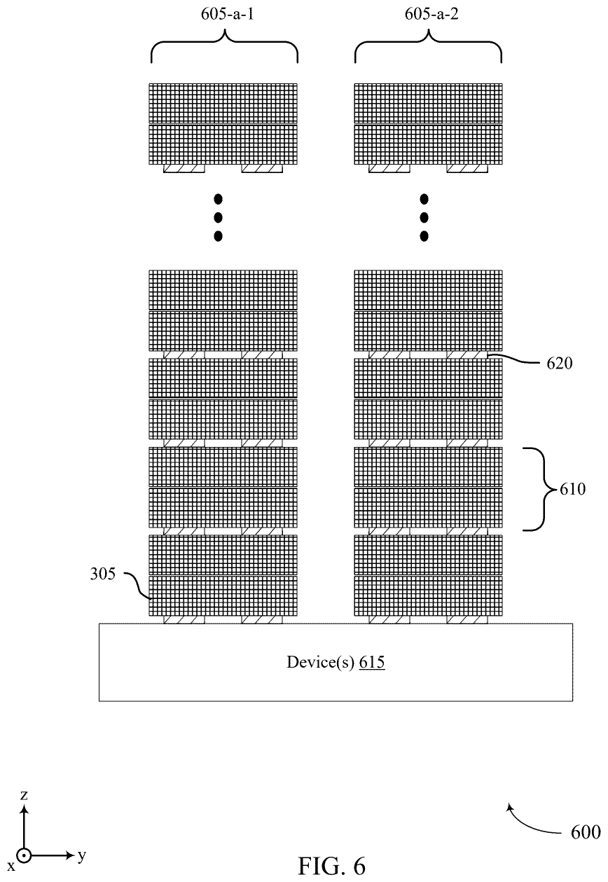

FIG. 6 shows an example of a system 600 that supports thermal structures for hybrid bonding in accordance with examples as disclosed herein. Aspects of the system 600 may further be described with reference to an x-direction, a y-direction, and a z-direction of the illustrated coordinate system, where the z-direction may be illustrative of a direction (e.g., a vertical direction, a thickness direction, a stack direction) that is orthogonal to or otherwise relative to a surface in an xy-plane (e.g., a substrate plane, a coupling plane) of the system 600. Although FIG. 6 illustrate examples of relative dimensions and quantities of various features, aspects of the system 600 may be implemented with other relative dimensions or quantities of such features in accordance with examples as disclosed herein. In some examples, the system 600 may illustrate a system involving bonded devices 305 that are stacked in a system.

For example, the system 600 may include one or more stacks 605, including stacks 605-a and 605-a-2, which may be representative of stacks of a set of any quantity of stacks 605 that may be arranged across the xy-plane. For example, the one or more stacks 605 may include an array of stacks each with a total quantity of devices 305 (e.g., may include at least 4, 8, 12, 16, 20, or 24 total dies in height, or 2, 4, 5, 8, 10, or 12 groups of paired devices 305). In some cases, the stacks 605 may be arranged on a material 301 during manufacture, or on one or more devices 615 (e.g., one or more logic dies formed from a logic wafer) during a lifetime of one or more devices 305. The stacks 605 may each include one or more stacked groups 610, where each group 610 may include one or more bonded devices 305 (e.g., hybrid bonded pair, hybrid bonded trio) as described herein. Each of the groups 610 may be coupled with a group above, a group below, or both, via one or more coupling components 620 (e.g., conductive pads 302, conductive pads 326).

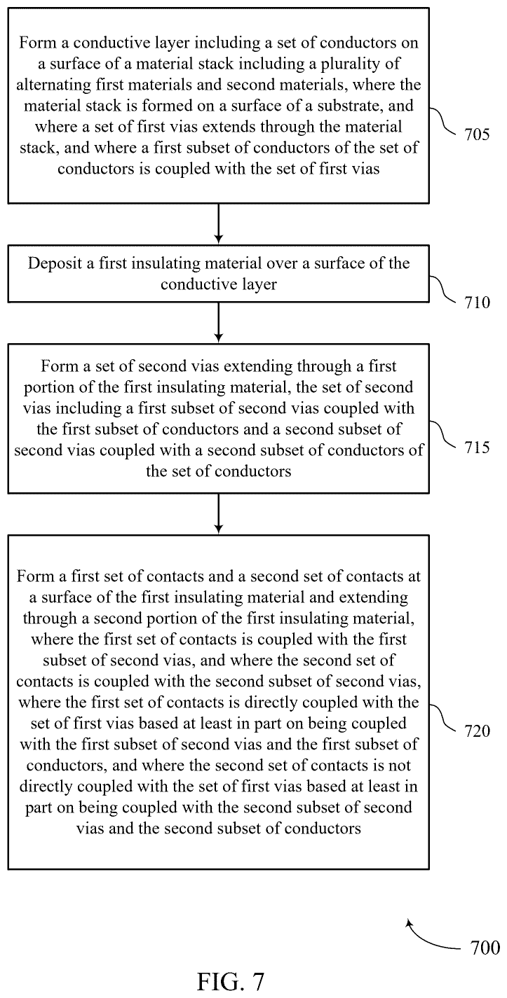

FIG. 7 shows a flowchart illustrating a method 700 that supports thermal structures for hybrid bonding in accordance with examples as disclosed herein. The operations of method 700 may be implemented by a manufacturing system or its components as described herein. For example, the operations of method 700 may be performed by a manufacturing system as described with reference to FIGS. 1 through 6. In some examples, a manufacturing system may execute a set of instructions to control the functional elements of the device to perform the described functions. Additionally, or alternatively, the manufacturing system may perform aspects of the described functions using special-purpose hardware.

At 705, the method may include forming a conductive layer including a set of conductors on a surface of a material stack including a plurality of alternating first materials and second materials, where the material stack is formed on a surface of a substrate, and where a set of first vias extends through the material stack, and where a first subset of conductors of the set of conductors is coupled with the set of first vias.

At 710, the method may include depositing a first insulating material over a surface of the conductive layer.

At 715, the method may include forming a set of second vias extending through a first portion of the first insulating material, the set of second vias including a first subset of second vias coupled with the first subset of conductors and a second subset of second vias coupled with a second subset of conductors of the set of conductors.

At 720, the method may include forming a first set of contacts and a second set of contacts at a surface of the first insulating material and extending through a second portion of the first insulating material, where the first set of contacts is coupled with the first subset of second vias, and where the second set of contacts is coupled with the second subset of second vias, where the first set of contacts is directly coupled with the set of first vias based at least in part on being coupled with the first subset of second vias and the first subset of conductors, and where the second set of contacts is not directly coupled with the set of first vias based at least in part on being coupled with the second subset of second vias and the second subset of conductors.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a conductive layer including a set of conductors on a surface of a material stack including a plurality of alternating first materials and second materials, where the material stack is formed on a surface of a substrate, and where a set of first vias extends through the material stack, and where a first subset of conductors of the set of conductors is coupled with the set of first vias; depositing a first insulating material over a surface of the conductive layer; forming a set of second vias extending through a first portion of the first insulating material, the set of second vias including a first subset of second vias coupled with the first subset of conductors and a second subset of second vias coupled with a second subset of conductors of the set of conductors; and forming a first set of contacts and a second set of contacts at a surface of the first insulating material and extending through a second portion of the first insulating material, where the first set of contacts is coupled with the first subset of second vias, and where the second set of contacts is coupled with the second subset of second vias, where the first set of contacts is directly coupled with the set of first vias based at least in part on being coupled with the first subset of second vias and the first subset of conductors, and where the second set of contacts is not directly coupled with the set of first vias based at least in part on being coupled with the second subset of second vias and the second subset of conductors.

Aspect 2: The method, apparatus, or non-transitory computer-readable medium of aspect 1, where forming the set of second vias includes operations, features, circuitry, logic, means, or instructions, or any combination thereof for etching the first insulating material to form a plurality of cavities and depositing one or more conductive materials within the plurality of cavities to form the set of second vias.

Aspect 3: The method, apparatus, or non-transitory computer-readable medium of aspect 2, further including operations, features, circuitry, logic, means, or instructions, or any combination thereof for depositing one or more additional insulating materials over a surface of the conductive layer including the set of conductors, where the first insulating material is deposited over the one or more additional insulating materials and etching the one or more additional insulating materials, where forming the plurality of cavities and depositing the one or more conductive materials is based at least in part on etching the first insulating material and the one or more additional insulating materials.

Aspect 4: The method, apparatus, or non-transitory computer-readable medium of any of aspects 1 through 3, further including operations, features, circuitry, logic, means, or instructions, or any combination thereof for forming a fifth set of contacts at the surface of the first insulating material and extending through the second portion of the first insulating material, where each contact of the fifth set of contacts is electrically isolated from the conductive layer.

Aspect 5: The method, apparatus, or non-transitory computer-readable medium of any of aspects 1 through 4, where one or more contacts of the first set of contacts are electrically coupled with one or more signals based at least in part on being coupled with one or more respective conductors of the set of conductors.

Aspect 6: The method, apparatus, or non-transitory computer-readable medium of any of aspects 1 through 5, where one or more contacts of the first set of contacts and one or more respective conductors of the set of conductors are electrically isolated from one or more signals based at least in part on the first insulating material.

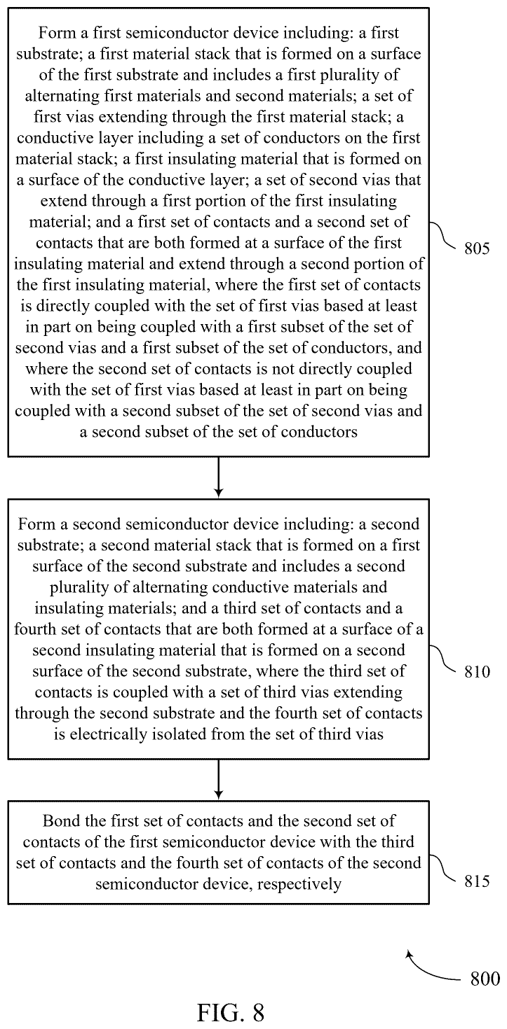

FIG. 8 shows a flowchart illustrating a method 800 that supports thermal structures for hybrid bonding in accordance with examples as disclosed herein. The operations of method 800 may be implemented by a manufacturing system or its components as described herein. For example, the operations of method 800 may be performed by a manufacturing system as described with reference to FIGS. 1 through 6. In some examples, a manufacturing system may execute a set of instructions to control the functional elements of the device to perform the described functions. Additionally, or alternatively, the manufacturing system may perform aspects of the described functions using special-purpose hardware.

At 805, the method may include forming a first semiconductor device including: a first substrate; a first material stack that is formed on a surface of the first substrate and includes a first plurality of alternating first materials and second materials; a set of first vias extending through the first material stack; a conductive layer including a set of conductors on the first material stack; a first insulating material that is formed on a surface of the conductive layer; a set of second vias that extend through a first portion of the first insulating material; and a first set of contacts and a second set of contacts that are both formed at a surface of the first insulating material and extend through a second portion of the first insulating material, where the first set of contacts is directly coupled with the set of first vias based at least in part on being coupled with a first subset of the set of second vias and a first subset of the set of conductors, and where the second set of contacts is not directly coupled with the set of first vias based at least in part on being coupled with a second subset of the set of second vias and a second subset of the set of conductors.

At 810, the method may include forming a second semiconductor device including: a second substrate; a second material stack that is formed on a first surface of the second substrate and includes a second plurality of alternating first materials and second materials; and a third set of contacts and a fourth set of contacts that are both formed at a surface of a second insulating material that is formed on a second surface of the second substrate, where the third set of contacts is coupled with a set of third vias extending through the second substrate and the fourth set of contacts is electrically isolated from the set of third vias.

At 815, the method may include bonding the first set of contacts and the second set of contacts of the first semiconductor device with the third set of contacts and the fourth set of contacts of the second semiconductor device, respectively.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:

Aspect 7: A method, apparatus, or non-transitory computer-readable medium including operations, features, circuitry, logic, means, or instructions, or any combination thereof for forming a first semiconductor device including: a first substrate; a first material stack that is formed on a surface of the first substrate and includes a first plurality of alternating first materials and second materials; a set of first vias extending through the first material stack; a conductive layer including a set of conductors on the first material stack; a first insulating material that is formed on a surface of the conductive layer; a set of second vias that extend through a first portion of the first insulating material; and a first set of contacts and a second set of contacts that are both formed at a surface of the first insulating material and extend through a second portion of the first insulating material, where the first set of contacts is directly coupled with the set of first vias based at least in part on being coupled with a first subset of the set of second vias and a first subset of the set of conductors, and where the second set of contacts is not directly coupled with the set of first vias based at least in part on being coupled with a second subset of the set of second vias and a second subset of the set of conductors; forming a second semiconductor device including: a second substrate; a second material stack that is formed on a first surface of the second substrate and includes a second plurality of alternating first materials and second materials; and a third set of contacts and a fourth set of contacts that are both formed at a surface of a second insulating material that is formed on a second surface of the second substrate, where the third set of contacts is coupled with a set of third vias extending through the second substrate and the fourth set of contacts is electrically isolated from the set of third vias; and bonding the first set of contacts and the second set of contacts of the first semiconductor device with the third set of contacts and the fourth set of contacts of the second semiconductor device, respectively.

Aspect 8: The method, apparatus, or non-transitory computer-readable medium of aspect 7, further including operations, features, circuitry, logic, means, or instructions, or any combination thereof for bonding the surface of the first insulating material with the surface of the second insulating material.

Aspect 9: The method, apparatus, or non-transitory computer-readable medium of any of aspects 7 through 8, further including operations, features, circuitry, logic, means, or instructions, or any combination thereof for forming a third semiconductor device including a third substrate and a third material stack that is formed on a first surface of the third substrate and includes a third plurality of alternating first materials and second materials, where the third semiconductor device includes a fifth set of contacts and a sixth set of contacts that are both formed at a surface of a third insulating material that is formed on a second surface of the third substrate, where the third set of contacts is coupled with a set of fourth vias extending through the third substrate and the fifth set of contacts is electrically isolated from the set of fourth vias and bonding a seventh set of contacts and an eighth set of contacts of the second semiconductor device with the fifth set of contacts and the sixth set of contacts of the third semiconductor device, respectively, the seventh set of contacts and the eighth set of contacts both formed at a surface of a fourth insulating material that is formed on a surface of a second conductive layer on the second material stack of the second semiconductor device.

Aspect 10: The method, apparatus, or non-transitory computer-readable medium of aspect 9, further including operations, features, circuitry, logic, means, or instructions, or any combination thereof for bonding the surface of the third insulating material with the surface of the fourth insulating material.

Aspect 11: The method, apparatus, or non-transitory computer-readable medium of any of aspects 7 through 10, further including operations, features, circuitry, logic, means, or instructions, or any combination thereof for coupling one or more first conductive pads of the second semiconductor device, the one or more first conductive pads coupled with the set of third vias, with one or more second conductive pads of a third semiconductor device including a third substrate, where one or more sets of contacts of the third semiconductor device are bonded with one or more sets of contacts of a fourth semiconductor device including a fourth substrate.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 12: A semiconductor system, including: a first semiconductor device including: a first substrate between a first surface and a second surface, a conductive layer including a set of conductors that is between the first substrate and the second surface, where a first subset of conductors of the set of conductors is directly coupled with a set of respective first vias extending through the first substrate and a second subset of conductors of the set of conductors is not directly coupled with the set of respective first vias; and a first set of contacts and a second set of contacts both at the second surface, where the first set of contacts is directly coupled with the set of respective first vias based at least in part on being coupled with a first subset of respective second vias of a first set of second vias and the first subset of conductors, and where the second set of contacts is not directly coupled with the set of respective first vias based at least in part on being coupled with a second subset of respective second vias of the first set of second vias and the second subset of conductors; and a second semiconductor device including: a second substrate between a first surface and a second surface of the second semiconductor device; and a third set of contacts and a fourth set of contacts both at the first surface of the second semiconductor device, where the third set of contacts is coupled with a set of respective third vias extending through the second substrate, where the fourth set of contacts is electrically isolated from the set of respective third vias, and where the first set of contacts and the second set of contacts at the second surface of the first semiconductor device are bonded with the third set of contacts and the fourth set of contacts at the first surface of the second semiconductor device, respectively.

Aspect 13: The semiconductor system of aspect 12, where the first semiconductor device further includes: a fifth set of contacts at the second surface of the first semiconductor device, where each contact of the fifth set of contacts is electrically isolated from the conductive layer of the first semiconductor device.

Aspect 14: The semiconductor system of any of aspects 12 through 13, where the first semiconductor device further includes: a first material stack of alternating first materials and second materials, where the first material stack is between the first substrate and the conductive layer of the first semiconductor device.

Aspect 15: The semiconductor system of any of aspects 12 through 14, where the second semiconductor device further includes: a second material stack of alternating first materials and second materials, where the second material stack is between the second substrate and the second surface of the second semiconductor device.

Aspect 16: The semiconductor system of any of aspects 12 through 15, further including: a third semiconductor device including a third substrate between a first surface and a second surface of the third semiconductor device, where the third semiconductor device includes a fifth set of contacts and a sixth set of contacts both at the first surface of the third semiconductor device, where the fifth set of contacts is coupled with a set of respective fourth vias extending through the third substrate, where the sixth set of contacts is electrically isolated from the set of respective fourth vias, and where a seventh set of contacts and an eighth set of contacts both at the second surface of the second semiconductor device are bonded with the fifth set of contacts and the sixth set of contacts at the first surface of the third semiconductor device, respectively.

Aspect 17: The semiconductor system of aspect 16, where: the second semiconductor device includes a second conductive layer including a second set of conductors that is between the second substrate and the second surface of the second semiconductor device, a first subset of conductors of the second set of conductors is directly coupled with the set of respective third vias extending through the second substrate and a second subset of conductors of the second set of conductors is not directly coupled with the set of respective third vias, the seventh set of contacts is directly coupled with the set of respective third vias based at least in part on being coupled with a first subset of respective second vias of a second set of second vias and the first subset of conductors of the second set of conductors, and the eighth set of contacts is not directly coupled with the set of respective third vias based at least in part on being coupled with a second subset of respective second vias of the second set of second vias and the second subset of conductors of the second set of conductors.

Aspect 18: The semiconductor system of any of aspects 12 through 17, further including: one or more first conductive pads coupled with the set of respective third vias extending through the second substrate of the second semiconductor device, where the one or more first conductive pads are coupled with one or more second conductive pads of a third semiconductor device including a third substrate, where one or more sets of contacts of the third semiconductor device are bonded with one or more sets of contacts of a fourth semiconductor device including a fourth substrate.

Aspect 19: The semiconductor system of any of aspects 12 through 18, where each contact of the first set of contacts is coupled with a respective second via of the first subset of respective second vias based at least in part on extending at least partially over a respective conductor of the first subset of conductors.

Aspect 20: The semiconductor system of any of aspects 12 through 19, where one or more contacts of the first set of contacts are electrically coupled with one or more signals based at least in part on being coupled with one or more respective conductors of the set of conductors.

Aspect 21: The semiconductor system of any of aspects 12 through 20, where one or more contacts of the first set of contacts and one or more respective conductors of the set of conductors are electrically isolated from one or more signals.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor system, comprising:
a first semiconductor device comprising:
a first substrate between a first surface and a second surface;
a conductive layer comprising a set of conductors that is between the first substrate and the second surface, wherein a first subset of conductors of the set of conductors is directly coupled with a set of respective first vias extending through the first substrate and a second subset of conductors of the set of conductors is not directly coupled with the set of respective first vias; and
a first set of contacts and a second set of contacts both at the second surface, wherein the first set of contacts is directly coupled with the set of respective first vias based at least in part on being coupled with a first subset of respective second vias of a first set of second vias and the first subset of conductors, and wherein the second set of contacts is not directly coupled with the set of respective first vias based at least in part on being coupled with a second subset of respective second vias of the first set of second vias and the second subset of conductors; and
a second semiconductor device comprising:
a second substrate between a first surface and a second surface of the second semiconductor device; and
a third set of contacts and a fourth set of contacts both at the first surface of the second semiconductor device, wherein the third set of contacts is coupled with a set of respective third vias extending through the second substrate, wherein the fourth set of contacts is electrically isolated from the set of respective third vias, and wherein the first set of contacts and the second set of contacts at the second surface of the first semiconductor device are bonded with the third set of contacts and the fourth set of contacts at the first surface of the second semiconductor device, respectively.

2. The semiconductor system of claim 1, wherein the first semiconductor device further comprises:
a fifth set of contacts at the second surface of the first semiconductor device, wherein each contact of the fifth set of contacts is electrically isolated from the conductive layer of the first semiconductor device.

3. The semiconductor system of claim 1, wherein the first semiconductor device further comprises:
a first material stack of alternating first materials and second materials, wherein the first material stack is between the first substrate and the conductive layer of the first semiconductor device.

4. The semiconductor system of claim 1, wherein the second semiconductor device further comprises:
a second material stack of alternating first materials and second materials, wherein the second material stack is between the second substrate and the second surface of the second semiconductor device.

5. The semiconductor system of claim 1, further comprising:
a third semiconductor device comprising a third substrate between a first surface and a second surface of the third semiconductor device, wherein the third semiconductor device comprises a fifth set of contacts and a sixth set of contacts both at the first surface of the third semiconductor device, wherein the fifth set of contacts is coupled with a set of respective fourth vias extending through the third substrate, wherein the sixth set of contacts is electrically isolated from the set of respective fourth vias, and wherein a seventh set of contacts and an eighth set of contacts both at the second surface of the second semiconductor device are bonded with the fifth set of contacts and the sixth set of contacts at the first surface of the third semiconductor device, respectively.

6. The semiconductor system of claim 5, wherein:
the second semiconductor device comprises a second conductive layer comprising a second set of conductors that is between the second substrate and the second surface of the second semiconductor device,
a first subset of conductors of the second set of conductors is directly coupled with the set of respective third vias extending through the second substrate and a second subset of conductors of the second set of conductors is not directly coupled with the set of respective third vias,
the seventh set of contacts is directly coupled with the set of respective third vias based at least in part on being coupled with a first subset of respective second vias of a second set of second vias and the first subset of conductors of the second set of conductors, and
the eighth set of contacts is not directly coupled with the set of respective third vias based at least in part on being coupled with a second subset of respective second vias of the second set of second vias and the second subset of conductors of the second set of conductors.

7. The semiconductor system of claim 1, further comprising:
one or more first conductive pads coupled with the set of respective third vias extending through the second substrate of the second semiconductor device, wherein the one or more first conductive pads are coupled with one or more second conductive pads of a third semiconductor device comprising a third substrate, wherein one or more sets of contacts of the third semiconductor device are bonded with one or more sets of contacts of a fourth semiconductor device comprising a fourth substrate.

8. The semiconductor system of claim 1, wherein each contact of the first set of contacts is coupled with a respective second via of the first subset of respective second vias based at least in part on extending at least partially over a respective conductor of the first subset of conductors.

9. The semiconductor system of claim 1, wherein one or more contacts of the first set of contacts are electrically coupled with one or more signals based at least in part on being coupled with one or more respective conductors of the set of conductors.

10. The semiconductor system of claim 1, wherein one or more contacts of the first set of contacts and one or more respective conductors of the set of conductors are electrically isolated from one or more signals.

11. A method of forming a semiconductor device, comprising:
forming a conductive layer comprising a set of conductors on a surface of a material stack comprising a plurality of alternating first materials and second materials, wherein the material stack is formed on a surface of a substrate, and wherein a set of first vias extends through the material stack, and wherein a first subset of conductors of the set of conductors is coupled with the set of first vias;
depositing a first insulating material over a surface of the conductive layer;
forming a set of second vias extending through a first portion of the first insulating material, the set of second vias comprising a first subset of second vias coupled with the first subset of conductors and a second subset of second vias coupled with a second subset of conductors of the set of conductors; and
forming a first set of contacts and a second set of contacts at a surface of the first insulating material and extending through a second portion of the first insulating material, wherein the first set of contacts is coupled with the first subset of second vias, and wherein the second set of contacts is coupled with the second subset of second vias, wherein the first set of contacts is directly coupled with the set of first vias based at least in part on being coupled with the first subset of second vias and the first subset of conductors, and wherein the second set of contacts is not directly coupled with the set of first vias based at least in part on being coupled with the second subset of second vias and the second subset of conductors.

12. The method of claim 11, wherein forming the set of second vias comprises:
etching the first insulating material to form a plurality of cavities; and
depositing one or more conductive materials within the plurality of cavities to form the set of second vias.

13. The method of claim 12, further comprising:
depositing one or more additional insulating materials over a surface of the conductive layer comprising the set of conductors, wherein the first insulating material is deposited over the one or more additional insulating materials; and
etching the one or more additional insulating materials, wherein forming the plurality of cavities and depositing the one or more conductive materials is based at least in part on etching the first insulating material and the one or more additional insulating materials.

14. The method of claim 11, further comprising:
forming a fifth set of contacts at the surface of the first insulating material and extending through the second portion of the first insulating material, wherein each contact of the fifth set of contacts is electrically isolated from the conductive layer.

15. The method of claim 11, wherein one or more contacts of the first set of contacts are electrically coupled with one or more signals based at least in part on being coupled with one or more respective conductors of the set of conductors.

16. The method of claim 11, wherein one or more contacts of the first set of contacts and one or more respective conductors of the set of conductors are electrically isolated from one or more signals based at least in part on the first insulating material.

17. A method of forming a semiconductor system, comprising:
forming a first semiconductor device comprising:
a first substrate;
a first material stack that is formed on a surface of the first substrate and comprises a first plurality of alternating first materials and second materials;
a set of first vias extending through the first material stack;
a conductive layer comprising a set of conductors on the first material stack;
a first insulating material that is formed on a surface of the conductive layer;
a set of second vias that extend through a first portion of the first insulating material; and
a first set of contacts and a second set of contacts that are both formed at a surface of the first insulating material and extend through a second portion of the first insulating material, wherein the first set of contacts is directly coupled with the set of first vias based at least in part on being coupled with a first subset of the set of second vias and a first subset of the set of conductors, and wherein the second set of contacts is not directly coupled with the set of first vias based at least in part on being coupled with a second subset of the set of second vias and a second subset of the set of conductors;
forming a second semiconductor device comprising:
a second substrate;
a second material stack that is formed on a first surface of the second substrate and comprises a second plurality of alternating first materials and second materials; and
a third set of contacts and a fourth set of contacts that are both formed at a surface of a second insulating material that is formed on a second surface of the second substrate, wherein the third set of contacts is coupled with a set of third vias extending through the second substrate and the fourth set of contacts is electrically isolated from the set of third vias; and
bonding the first set of contacts and the second set of contacts of the first semiconductor device with the third set of contacts and the fourth set of contacts of the second semiconductor device, respectively.

18. The method of claim 17, further comprising:
bonding the surface of the first insulating material with the surface of the second insulating material.

19. The method of claim 17, further comprising:
forming a third semiconductor device comprising a third substrate and a third material stack that is formed on a first surface of the third substrate and comprises a third plurality of alternating first materials and second materials, wherein the third semiconductor device comprises a fifth set of contacts and a sixth set of contacts that are both formed at a surface of a third insulating material that is formed on a second surface of the third substrate, wherein the third set of contacts is coupled with a set of fourth vias extending through the third substrate and the fifth set of contacts is electrically isolated from the set of fourth vias; and
bonding a seventh set of contacts and an eighth set of contacts of the second semiconductor device with the fifth set of contacts and the sixth set of contacts of the third semiconductor device, respectively, the seventh set of contacts and the eighth set of contacts both formed at a surface of a fourth insulating material that is formed on a surface of a second conductive layer on the second material stack of the second semiconductor device.

20. The method of claim 19, further comprising:
bonding the surface of the third insulating material with the surface of the fourth insulating material.

21. The method of claim 17, further comprising:
coupling one or more first conductive pads of the second semiconductor device, the one or more first conductive pads coupled with the set of third vias, with one or more second conductive pads of a third semiconductor device comprising a third substrate, wherein one or more sets of contacts of the third semiconductor device are bonded with one or more sets of contacts of a fourth semiconductor device comprising a fourth substrate.

22. A product formed by a process, the process comprising:
forming a conductive layer comprising a set of conductors on a surface of a material stack comprising a plurality of alternating first materials and second materials, wherein the material stack is formed on a surface of a substrate, and wherein a set of first vias extends through the material stack, and wherein a first subset of conductors of the set of conductors is coupled with the set of first vias;
depositing a first insulating material over a surface of the conductive layer;
forming a set of second vias extending through a first portion of the first insulating material, the set of second vias comprising a first subset of second vias coupled with the first subset of conductors and a second subset of second vias coupled with a second subset of conductors of the set of conductors; and
forming a first set of contacts and a second set of contacts at a surface of the first insulating material and extending through a second portion of the first insulating material, wherein the first set of contacts is coupled with the first subset of second vias, and wherein the second set of contacts is coupled with the second subset of second vias, wherein the first set of contacts is directly coupled with the set of first vias based at least in part on being coupled with the first subset of second vias and the first subset of conductors, and wherein the second set of contacts is not directly coupled with the set of first vias based at least in part on being coupled with the second subset of second vias and the second subset of conductors.

23. The product of claim 22, wherein forming the set of second vias comprises:
etching the first insulating material to form a plurality of cavities; and
depositing one or more conductive materials within the plurality of cavities to form the set of second vias.

24. The product of claim 23, the process further comprising:
depositing one or more additional insulating materials over a surface of the conductive layer comprising the set of conductors, wherein the first insulating material is deposited over the one or more additional insulating materials; and
etching the one or more additional insulating materials, wherein forming the plurality of cavities and depositing the one or more conductive materials is based at least in part on etching the first insulating material and the one or more additional insulating materials.

25. The product of claim 22, the process further comprising:
forming a fifth set of contacts at the surface of the first insulating material and extending through the second portion of the first insulating material, wherein each contact of the fifth set of contacts is electrically isolated from the conductive layer.

26. The product of claim 22, wherein:
one or more contacts of the first set of contacts are electrically coupled with one or more signals based at least in part on being coupled with one or more respective conductors of the set of conductors; and
one or more contacts of the first set of contacts and one or more respective conductors of the set of conductors are electrically isolated from one or more signals based at least in part on the first insulating material.

27. A product formed by a process, the process comprising:
forming a first semiconductor device comprising:
a first substrate;
a first material stack that is formed on a surface of the first substrate and comprises a first plurality of alternating first materials and second materials;
a set of first vias extending through the first material stack;
a conductive layer comprising a set of conductors on the first material stack;
a first insulating material that is formed on a surface of the conductive layer;
a set of second vias that extend through a first portion of the first insulating material; and
a first set of contacts and a second set of contacts that are both formed at a surface of the first insulating material and extend through a second portion of the first insulating material, wherein the first set of contacts is directly coupled with the set of first vias based at least in part on being coupled with a first subset of the set of second vias and a first subset of the set of conductors, and wherein the second set of contacts is not directly coupled with the set of first vias based at least in part on being coupled with a second subset of the set of second vias and a second subset of the set of conductors;
forming a second semiconductor device comprising:
a second substrate;
a second material stack that is formed on a first surface of the second substrate and comprises a second plurality of alternating first materials and second materials; and
a third set of contacts and a fourth set of contacts that are both formed at a surface of a second insulating material that is formed on a second surface of the second substrate, wherein the third set of contacts is coupled with a set of third vias extending through the second substrate and the fourth set of contacts is electrically isolated from the set of third vias; and
bonding the first set of contacts and the second set of contacts of the first semiconductor device with the third set of contacts and the fourth set of contacts of the second semiconductor device, respectively.

28. The product of claim 27, the process further comprising:
bonding the surface of the first insulating material with the surface of the second insulating material.

29. The product of claim 27, the process further comprising:
forming a third semiconductor device comprising a third substrate and a third material stack that is formed on a first surface of the third substrate and comprises a third plurality of alternating first materials and second materials, wherein the third semiconductor device comprises a fifth set of contacts and a sixth set of contacts that are both formed at a surface of a third insulating material that is formed on a second surface of the third substrate, wherein the third set of contacts is coupled with a set of fourth vias extending through the third substrate and the fifth set of contacts is electrically isolated from the set of fourth vias;
bonding a seventh set of contacts and an eighth set of contacts of the second semiconductor device with the fifth set of contacts and the sixth set of contacts of the third semiconductor device, respectively, the seventh set of contacts and the eighth set of contacts both formed at a surface of a fourth insulating material that is formed on a surface of a second conductive layer on the second material stack of the second semiconductor device; and
bonding the surface of the third insulating material with the surface of the fourth insulating material.

30. The product of claim 27, the process further comprising:
coupling one or more first conductive pads of the second semiconductor device, the one or more first conductive pads coupled with the set of third vias, with one or more second conductive pads of a third semiconductor device comprising a third substrate, wherein one or more sets of contacts of the third semiconductor device are bonded with one or more sets of contacts of a fourth semiconductor device comprising a fourth substrate.
